(19) United States
(12) Patent Application Publication
(10) Pub. No.: US 2026/0305087 A1
(43) Pub. Date: Oct. 1, 2026

(54) DISPLAY PANEL AND ELECTRONIC DEVICE

(71) Applicant: Samsung Display Co., Ltd., Yongin-si (KR)

(72) Inventors: Changkyu Jin, Yongin-si (KR); Heyjin Shin, Yongin-si (KR)

(21) Appl. No.: 19/563,612

(22) Filed: Mar. 11, 2026

(30) Foreign Application Priority Data
Mar. 27, 2025 (KR) 10-2025-0039695

(51) Int. Cl. H10K 59/126; H10K 59/131

(52) U.S. Cl. CPC H10K 59/126; H10K 59/131

(57) ABSTRACT

A display panel includes: at least one display element; a pixel circuit connected to the at least one display element and comprising a conductive layer configured to receive an emission control signal; a connection electrode on the conductive layer, at least partially overlapping the conductive layer in a plan view, and connected to a pixel electrode of the at least one display element; and a shielding unit between the conductive layer and the connection electrode to overlap a portion of the conductive layer where the conductive layer and the connection electrode overlap each other.

### CROSS-REFERENCE TO RELATED APPLICATION

The present application claims priority to and the benefit of Korean Patent Application No. 10-2025-0039695, filed on Mar. 27, 2025, in the Korean Intellectual Property Office, the entire disclosure of which is incorporated herein by reference.

### BACKGROUND

### 1. Field

Aspects of some embodiments of the present disclosure relate to a display panel and an electronic device including the display panel.

### 2. Description of the Related Art

Mobility-based electronic devices are widely used. In addition to small electronic devices such as mobile phones, tablet personal computers have been widely used in recent years as mobile electronic devices.

A mobile electronic device includes a display panel that provides visual information, such as an image or a video, to a user to support various functions. Recently, as the size of other components for driving a display panel has been reduced, the proportion of the display panel in an electronic device has gradually increased, and a structure that may be bent by a certain angle from a flat state has been developed.

The above information disclosed in this Background section is only for enhancement of understanding of the background and therefore the information discussed in this Background section does not necessarily constitute prior art. SUMMARY

Aspects of some embodiments of the present disclosure relate to a device, and for example, to a display panel and an electronic device including the display panel.

Generally, a display panel may include a plurality of lines and a plurality of conductive patterns. At this time, a conductive pattern connected to a line to which an emission control signal is applied among the plurality of lines may at least partially overlap another conductive pattern, which are located on different layers from that of the conductive pattern, in a plan view. At this time, the conductive pattern to which the emission control signal is applied and the other conductive patterns may affect each other, which may cause a problem in which the brightness of a pixel of the display panel is not constant and varies when the pixel emits light. One or more embodiments include a display panel and electronic device in which signal interference between conductive patterns located on different layers is reduced.

Additional aspects will be set forth in part in the description which follows and, in part, will be apparent from the description, or may be learned by practice of the presented embodiments of the disclosure.

According to one or more embodiments, a display panel includes at least one display element, a pixel circuit connected to the at least one display element and including a conductive layer to which an emission control signal is applied, a connection electrode located on the conductive layer, at least partially overlapping the conductive layer in a plan view, and connected to a pixel electrode of the at least one display element, and a shielding unit between the conductive layer and the connection electrode to overlap a portion of the conductive layer where the conductive layer and the connection electrode overlap each other.

According to some embodiments, the shielding unit may be applied with an initialization voltage or a bias voltage.

According to some embodiments, the shielding unit may have at least a portion bent.

According to some embodiments, a width of the shielding unit in a first direction may be greater than a width of a portion of the conductive layer, the portion overlapping the shielding unit.

According to some embodiments, the conductive layer may include a first portion and a second portion extending from the first portion in a direction different from a longitudinal direction of the first portion.

According to some embodiments, the pixel circuit may further include a semiconductor layer overlapping at least a portion of the conductive layer.

According to some embodiments, the semiconductor layer may include polycrystalline silicon.

According to some embodiments, the display panel may further include an emission control line on a different layer from the conductive layer of the pixel circuit and connected to the conductive layer to apply the emission control signal to the conductive layer.

According to some embodiments, at least a portion of the shielding unit may cross the emission control line.

According to some embodiments, the shielding unit and the emission control line may extend in a same direction.

According to some embodiments, the conductive layer may be directly connected to the emission control line.

According to some embodiments, a constant voltage may be applied to the shielding unit.

According to some embodiments, the display panel may further include an insulating layer between the shielding unit and the conductive layer.

According to one or more embodiments of the present disclosure, a display panel includes at least one display element, a pixel circuit connected to the at least one display element and including a conductive layer to which an emission control signal is applied, a connection electrode on the conductive layer, at least partially overlapping the conductive layer in a plan view, and connected to a pixel electrode of the at least one display element, and a shielding unit between the conductive layer and the connection electrode to overlap a portion of the conductive layer where the conductive layer and the connection electrode overlap each other, and including an initialization voltage line or a bias voltage line to which a constant voltage is applied.

According to one or more embodiments of the present disclosure, an electronic device includes a display panel and a memory connected to the display panel, wherein the display panel includes at least one display element, a pixel circuit connected to the at least one display element and including a conductive layer to which an emission control signal is applied, a connection electrode on the conductive layer, at least partially overlapping the conductive layer in a plan view, and connected to a pixel electrode of the at least one display element, and a shielding unit between the conductive layer and the connection electrode to overlap a portion of the conductive layer where the conductive layer and the connection electrode overlap each other.

According to some embodiments, the shielding unit may be applied with an initialization voltage or a bias voltage.

According to some embodiments, a width of the shielding unit in a first direction may be greater than a width of a portion of the conductive layer, the portion overlapping the shielding unit.

According to some embodiments, the display panel may further include an emission control line on a different layer from the conductive layer of the pixel circuit and connected to the conductive layer to apply the emission control signal to the conductive layer.

According to some embodiments, the conductive layer may be directly connected to the emission control line.

According to some embodiments, a constant voltage may be applied to the shielding unit.

Other aspects, features, and characteristics other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are plan views each schematically illustrating a display panel according to some embodiments;

FIG. 2 is a schematic block diagram of a display panel according to some embodiments;

FIG. 3 is an equivalent circuit diagram of a pixel according to some embodiments;

FIG. 4 is a schematic cross-sectional view of a portion of a display panel according to some embodiments;

FIG. 5A is a schematic plan view showing the positions of elements located in a pixel circuit of a display panel according to some embodiments;

FIG. 5B is a schematic plan view showing a portion of FIG. 5A;

FIG. 5C is a schematic plan view of a portion of a pixel circuit of a display panel according to some embodiments;

FIG. 5D is a cross-sectional view taken along a line A-A′ of FIG. 5A;

FIGS. 6 to 15 are schematic layout diagrams showing, by each layer, elements located in a pixel circuit of a display panel according to some embodiments;

FIG. 16 is a block diagram of an electronic device according to some embodiments; and

FIGS. 17 to 19 are schematic diagrams of electronic devices according to various embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to aspects of some embodiments and drawings described below in more detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited by the above terms.

In the following embodiments, an expression used in the singular encompasses the expression of the plural, unless it has a clearly different meaning in the context.

In the following embodiments, it is to be understood that the terms such as “including,” “having,” and “comprising” are intended to indicate the existence of the features, or elements disclosed in the specification, and are not intended to preclude the possibility that one or more other features or elements may exist or may be added.

It will be understood that when a layer, region, or element is referred to as being formed on another layer, region, or element, it can be directly or indirectly formed on the other layer, region, or element, that is, for example, intervening layers, regions, or elements may be present.

Sizes of elements in the drawings may be exaggerated or reduced for convenience of explanation. For example, because sizes and thicknesses of components in the drawings are arbitrarily illustrated for convenience of explanation, the following embodiments are not limited thereto.

The x direction, the y direction, and the z direction are not limited to directions corresponding to three axes on the orthogonal coordinates system, and may be interpreted in a broad sense including the same. For example, the x direction, the y direction, and the z direction may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

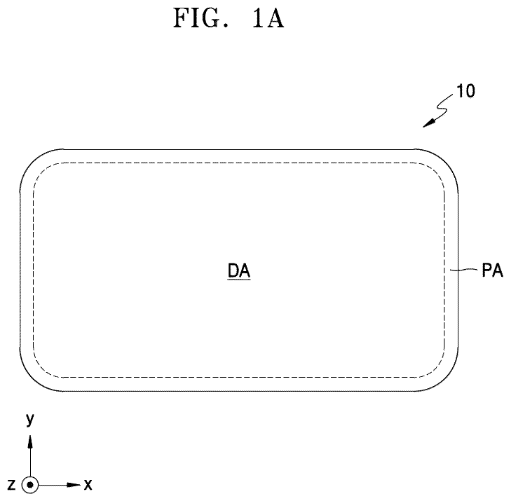

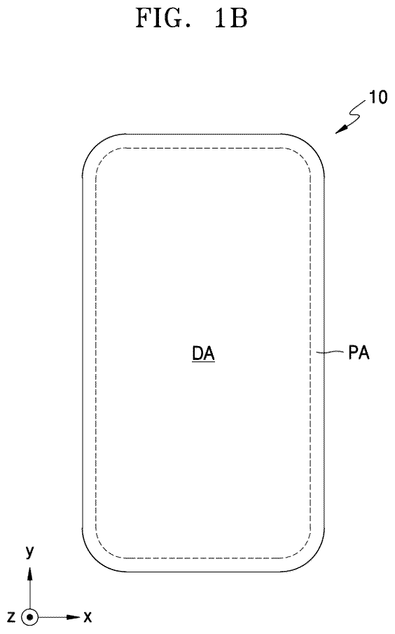

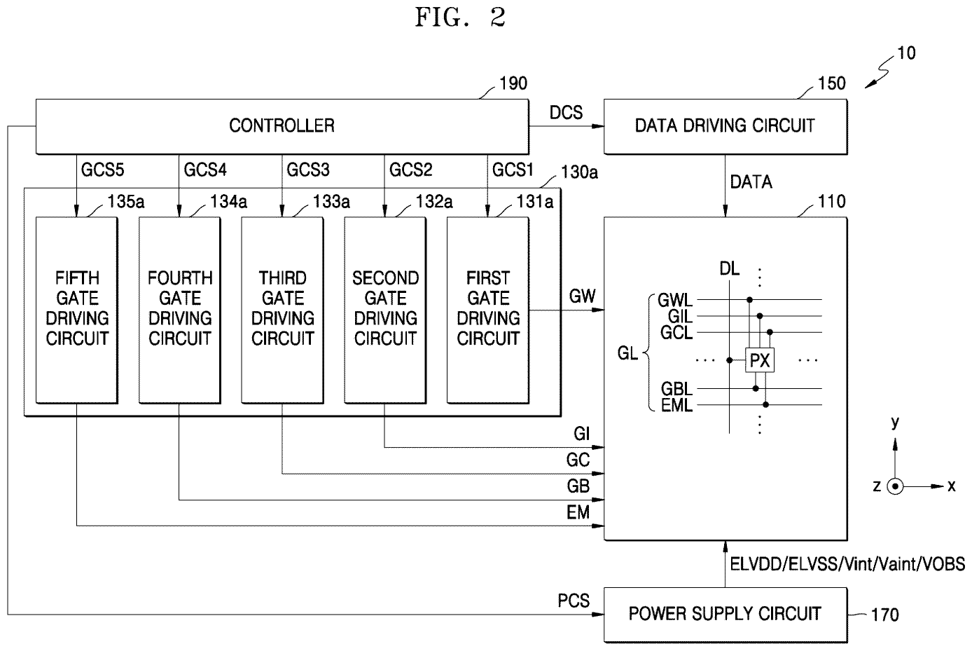

FIGS. 1A and 1B are plan views each schematically illustrating a display panel according to some embodiments. FIG. 2 is a schematic block diagram of a display panel according to some embodiments.

Referring to FIGS. 1A and 1B, a display panel 10 may include a display area DA displaying images and a peripheral area PA outside (e.g., in a periphery or outside a footprint of) the display area DA. The display area DA may be entirely surrounded by the peripheral area PA.

In a plan view of the display area DA, the display area DA may have a rectangular shape. According to some embodiments, the display area DA may have another polygonal shape such as a triangular shape, a pentagonal shape, a hexagonal shape, or the like, a circular shape, an elliptical shape, an atypical (or irregular) shape, or the like. A corner of an edge of the display area DA may have a round shape. According to some embodiments, the display panel 10 may have a display area DA having a shape in which a length in an x direction is greater than a length in a y direction, as shown in FIG. 1A. According to some embodiments, the display panel 10 may have a display area DA having a shape in which a length in the y direction is greater than a length in the x direction, as shown in FIG. 1B.

Referring to FIG. 2, the display panel 10 according to some embodiments may include a pixel unit 110, a gate driving circuit 130a, a data driving circuit 150, a power supply circuit 170, and a controller 190.

The pixel unit 110 may be provided in the display area DA. Various conductive lines transferring electrical signals to be applied to the display area DA, outer circuits electrically connected to pixel circuits, and pads to which a printed circuit board or a driver integrated circuit (IC) chip is attached may be positioned in the peripheral area PA. For example, the gate driving circuit 130a, the data driving circuit 150, the power supply circuit 170, and the controller 190 may be provided in the peripheral area PA.

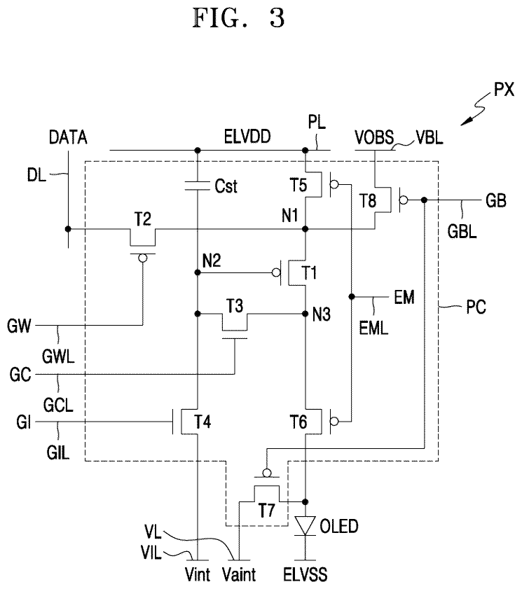

Pixels PX may be located in the pixel unit 110. The pixels PX may be repeatedly arranged in a certain pattern in an x direction (row direction) and a y direction (column direction). The pixels PX may be arranged in various forms, such as a stripe arrangement, a Pentile® arrangement, a diamond arrangement, a mosaic arrangement, or the like, to implement an image. Each pixel PX of the pixel unit 110 may include an organic light-emitting diode OLED (refer to FIG. 3) as a display element, and a pixel circuit connected to the organic light-emitting diode OLED. Each pixel PX may emit, for example, red, green, blue, or white light through the organic light-emitting diode OLED. For example, the pixels PX may include a first pixel emitting light of a first color, a second pixel emitting light of a second color, and a third pixel emitting light of a third color. For example, the first pixel may be a green pixel, the second pixel may be a red pixel, and the third pixel may be a blue pixel.

Gate lines GL may be arranged in the pixel unit 110 to be spaced apart from each other at regular intervals in the y direction (e.g., the column direction). Each of the gate lines GL may extend in the x direction (e.g., the row direction) and be connected to pixels PX positioned in the same row (row line).

Data lines DL may be arranged in the pixel unit 110 to be spaced apart from each other at regular intervals in the x direction. Each of the data lines DL may extend in the y direction and be connected to pixels PX positioned in the same column (column line). Each of the data lines DL may be configured to transmit a data signal DATA to each of the pixels PX in the same column in synchronization with a gate signal.

The gate driving circuit 130a may be connected to the gate lines GL, generate a gate signal in response to a control signal from the controller 190, and sequentially supply the generated gate signal to the gate lines GL. A gate line GL may be connected to a gate of a transistor included in the pixel PX. A gate signal may be a gate control signal controlling turn-on and turn-off of a transistor having a gate connected to the gate line GL. The gate signal may be a signal including a gate-on voltage at which the transistor may be turned on and a gate-off voltage at which the transistor may be turned off.

Referring to FIG. 2, according to some embodiments, the gate driving circuit 130a may include gate driving circuits. For example, the gate driving circuit 130a may include a first gate driving circuit 131a, a second gate driving circuit 132a, a third gate driving circuit 133a, a fourth gate driving circuit 134a, and a fifth gate driving circuit 135a. In some cases, some gate driving circuits may be integrated.

Gate lines GL may include first gate lines GWL electrically connected to the first gate driving circuit 131a, second gate lines GIL electrically connected to the second gate driving circuit 132a, third gate lines GCL electrically connected to the third gate driving circuit 133a, fourth gate lines GBL electrically connected to the fourth gate driving circuit 134a, and fifth gate lines EML electrically connected to the fifth gate driving circuit 135a.

The first gate driving circuit 131a may be electrically connected to the first gate lines GWL and sequentially supply a first gate signal GW to the first gate lines GWL in response to a first control signal GCS1. The second gate driving circuit 132a may be electrically connected to the second gate lines GIL and sequentially supply a second gate signal GI to the second gate lines GIL in response to a second control signal GCS2. The third gate driving circuit 133a may be electrically connected to the third gate lines GCL and sequentially supply a third gate signal GC to the third gate lines GCL in response to a third control signal GCS3. The fourth gate driving circuit 134a may be electrically connected to the fourth gate lines GBL and sequentially supply a fourth gate signal GB to the fourth gate lines GBL in response to a fourth control signal GCS4. The fifth gate driving circuit 135a may be electrically connected to the fifth gate lines EML and sequentially supply a fifth gate signal EM to the fifth gate lines EML in response to a fifth control signal GCS5.

The data driving circuit 150 may be connected to the data lines DL, and may supply a data signal DATA to the data lines DL in response to a sixth control signal DCS from the controller 190. The data signal DATA supplied to a data line DL may be supplied to the pixel PX to which a gate signal is supplied. The data driving circuit 150 may convert image data having a gray-scale from the controller 190 into a data signal DATA in a form of voltage or current.

The power supply circuit 170 may generate voltages necessary for driving the pixel PX in response to a seventh control signal PCS from the controller 190. The power supply circuit 170 may generate and supply a first power voltage ELVDD and a second power voltage ELVSS to the pixels PX. The first power voltage ELVDD may be a high-level voltage provided to a first electrode (pixel electrode or anode) of a display element included in the pixel PX. The second power voltage ELVSS may be a low-level voltage provided to a second electrode (opposite electrode or cathode) of a display element included in the pixel PX. The power supply circuit 170 may also generate and supply a bias voltage VOBS, an initialization voltage Vint, and an initialization voltage Vaint to the pixels PX.

A voltage level of the first power voltage ELVDD may be higher than a voltage level of the second power voltage ELVSS. A voltage level of the bias voltage VOBS may be lower than the voltage level of the first power voltage ELVDD. A voltage level of the initialization voltage Vint may be lower than the voltage level of the second power voltage ELVSS. A voltage level of the initialization voltage Vaint may be higher than the voltage level of the initialization voltage Vint. The voltage level of the initialization voltage Vaint may be equal to the voltage level of the second power voltage ELVSS or higher than the voltage level of the second power voltage ELVSS.

The controller 190 may generate the first to seventh control signals GCS1, GCS2, GCS3, GCS4, GCS5, DCS, and PCS and supply the same to the first to fifth gate driving circuits 131a, 132a, 133a, 134a, and 135a, the data driving circuit 150, and the power supply circuit 170, respectively. The first to fifth control signals GCS1, GCS2, GCS3, GCS4, and GCS5 output to the gate driving circuit 130a may include clock signals and gate start signals. The sixth control signal DCS output to the data driving circuit 150 may include data start signals and clock signals.

The display panel 10 may include a substrate. The pixels PX may be located in the display area DA of the substrate. A portion or the entirety of the gate driving circuit 130a may be directly formed in the peripheral area PA of the substrate during a process of forming a transistor configuring a pixel circuit in the display area DA of the substrate. The data driving circuit 150, the power supply circuit 170, and the controller 190 may each be formed in a form of a separate IC chip or may be formed in one IC chip to be located on a flexible printed circuit board (FPCB) electrically connected to a pad located on one side of the substrate. According to some embodiments, the data driving circuit 150, the power supply circuit 170, and the controller 190 may be directly located on the substrate by using a method of chip on glass (COG) or chip on plastic (COP).

FIG. 3 is an equivalent circuit diagram of a pixel according to some embodiments. Although FIG. 3 illustrates various components in a pixel circuit according to some embodiments, embodiments according to the present disclosure are not limited thereto, and according to various embodiments, the pixel circuit may include additional components, or fewer components, without departing from the spirit and scope of embodiments according to the present disclosure.

Referring to FIG. 3, the pixel PX may include an organic light-emitting diode OLED and a pixel circuit PC electrically connected to the organic light-emitting diode OLED. The pixel circuit PC may include first to eighth transistors T1, T2, T3, T4, T5, T6, T7, and T8 and a first capacitor Cst. The pixel circuit PC may be electrically connected to a data line DL, a first gate line GWL, a second gate line GIL, a third gate line GCL, a fourth gate line GBL, and a fifth gate line EML. The fifth gate line EML may be referred to as an emission control line, and a fifth gate signal EM transferred by the fifth gate line EML may be referred to as an emission control signal. In addition, the pixel circuit PC may be electrically connected to a node initialization voltage line VIL, an initialization voltage line VL, and a first power voltage line PL.

FIG. 3 illustrates that, among the first to eighth transistors T1 to T8, the third transistor T3 and the fourth transistor T4 are N-type transistors, and the remaining transistors are P-type transistors. According to the type (N-type or P-type) of transistors and/or operating conditions, a first terminal of a transistor may be a source electrode or a drain electrode, and a second terminal thereof may be another electrode different from the first terminal. For example, when the first terminal is a source electrode, the second terminal may be a drain electrode. A gate of the transistor may be a gate electrode.

The first transistor T1 may be connected between the first power voltage line PL and the organic light-emitting diode OLED. The first transistor T1 may be connected between a first node N1 and a third node N3. The first transistor T1 may be connected to the first power voltage line PL via the fifth transistor T5, and may be electrically connected to the organic light-emitting diode OLED via the sixth transistor T6. The first transistor T1 may include a gate connected to a second node N2, a first terminal connected to the first node N1, and a second terminal connected to the third node N3. The first power voltage line PL may be configured to transmit the first power voltage ELVDD to the first transistor T1. The first transistor T1 may serve as a driving transistor and receive the data signal DATA in response to a switching operation of the second transistor T2 to supply a driving current to the organic light-emitting diode OLED.

The second transistor T2 (data write transistor) may be connected between the data line DL and the first node N1. The second transistor T2 may be connected to the first power voltage line PL via the fifth transistor T5. A gate of the second transistor T2 may be connected to the first gate line GWL. The second transistor T2 may include the gate connected to the first gate line GWL, a first terminal connected to the data line DL, and a second terminal connected to the first node N1. The second transistor T2 may be turned on in response to the first gate signal GW received through the first gate line GWL and may perform a switching operation of delivering the data signal DATA delivered through the data line DL to the first node N1.

The third transistor T3 (compensation transistor) may be connected between the second node N2 and the third node N3. The third transistor T3 may be electrically connected to the organic light-emitting diode OLED via the sixth transistor T6. The third transistor T3 may include a gate connected to the third gate line GCL, a first terminal connected to the second node N2, and a second terminal connected to the third node N3. The third transistor T3 may be turned on in response to the third gate signal GC received through the third gate line GCL to diode-connect the first transistor T1, thereby compensating for a threshold voltage of the first transistor T1.

The fourth transistor T4 (node initialization transistor) may be connected between the second node N2 and the node initialization voltage line VIL. The fourth transistor T4 may include a gate connected to the second gate line GIL, a first terminal connected to the second node N2, and a second terminal connected to the node initialization voltage line VIL. The fourth transistor T4 may be turned on in response to the second gate signal GI received through the second gate line GIL and deliver the initialization voltage Vint to the gate of the first transistor T1 to initialize the gate of the first transistor T1.

The fifth transistor T5 (first emission control transistor) may be connected between the first power voltage line PL and the first node N1. The sixth transistor T6 (second emission control transistor) may be connected between the third node N3 and the organic light-emitting diode OLED. The fifth transistor T5 may include a gate connected to the fifth gate line EML, a first terminal connected to the first power voltage line PL, and a second terminal connected to the first node N1. The sixth transistor T6 may include a gate connected to the fifth gate line EML, a first terminal connected to the third node N3, and a second terminal connected to a pixel electrode of the organic light-emitting diode OLED. When the fifth transistor T5 and the sixth transistor T6 are simultaneously (or concurrently) turned on in response to a fifth gate signal EM received through the fifth gate line EML, a driving current flows to the organic light-emitting diode OLED.

The seventh transistor T7 (initialization transistor) may be connected between the organic light-emitting diode OLED and the initialization voltage line VL. The seventh transistor T7 may include a gate connected to the fourth gate line GBL, a first terminal connected to the second terminal of the sixth transistor T6 and the pixel electrode of the organic light-emitting diode OLED, and a second terminal connected to the initialization voltage line VL. The seventh transistor T7 may be turned on in response to the fourth gate signal GB received through the fourth gate line GBL and configured to transmit the initialization voltage Vaint to the pixel electrode of the organic light-emitting diode OLED to initialize the pixel electrode of the organic light-emitting diode OLED. The eighth transistor T8 may be simultaneously (or concurrently) turned on with the seventh transistor T7 in response to the fourth gate signal GB.

The eighth transistor T8 (bias transistor) may be connected between the first node N1 and a bias voltage line VBL. The eighth transistor T8 may include a gate connected to the fourth gate line GBL, a first terminal connected to the bias voltage line VBL, and a second terminal connected to the first node N1. The eighth transistor T8 may be turned on in response to the fourth gate signal GB received through the fourth gate line GBL and apply the bias voltage VOBS to the first terminal of the first transistor T1 to preset a voltage suitable for a subsequent operation of the first transistor T1 at the first terminal.

The first capacitor Cst may include a first electrode connected to the gate of the first transistor T1 and a second electrode connected to the first power voltage line PL. The first capacitor Cst may maintain a voltage applied to the gate of the first transistor T1 by storing and maintaining a voltage corresponding to the difference between voltages of both ends of the first power voltage line PL and the gate of the first transistor T1.

The organic light-emitting diode OLED may include the pixel electrode and an opposite electrode, and the opposite electrode may receive the second power voltage ELVSS. The organic light-emitting diode OLED displays an image by receiving a driving current from the first transistor T1 and emitting light.

FIG. 3 illustrates that the pixel circuit PC includes eight transistors and one capacitor, but the disclosure is not limited thereto. The number of transistors and capacitors included in the pixel circuit PC may be designed and changed in various ways.

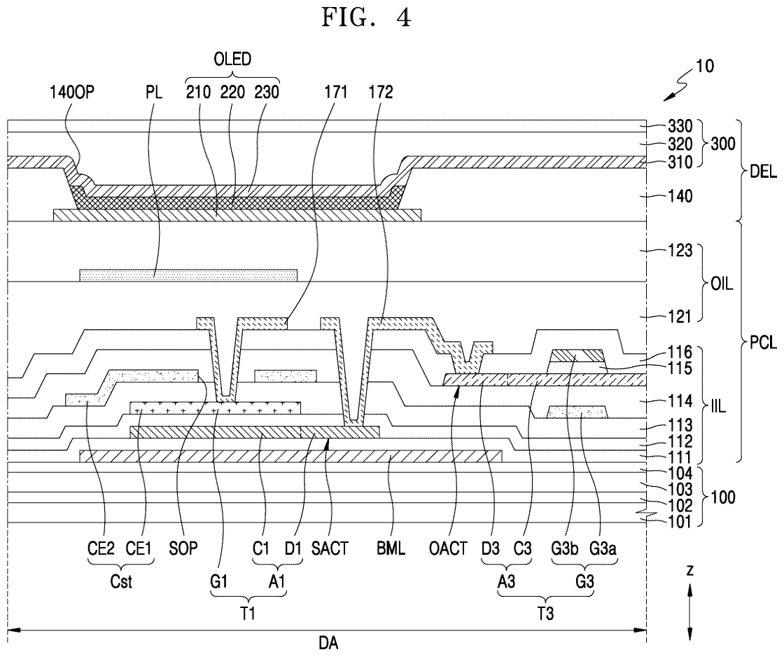

FIG. 4 is a schematic cross-sectional view of a portion of a display panel according to some embodiments.

Referring to FIG. 4, the display area DA may include pixel areas in which pixel circuits PC of each of the pixels PX of the pixel unit 110 are located. The pixel areas may be arranged in an x direction (row direction) and a y direction (column direction). According to some embodiments, the display panel 10 may include a substrate 100, a pixel circuit layer PCL, and a light-emitting diode layer DEL.

The pixel circuit layer PCL may be defined as a pixel circuit. The pixel circuit layer PCL may include components of transistors and capacitors and insulating layers located below and/or above the components. In this regard, FIG. 4 illustrates the first transistor T1, the third transistor T3, and the first capacitor Cst among the transistors and capacitors included in a pixel circuit. In addition, the pixel circuit layer PCL may include inorganic insulating layers IIL and organic insulating layers OIL. For example, as shown in FIG. 4, the inorganic insulating layers IIL may include a buffer layer 111, a first gate insulating layer 112, a first interlayer insulating layer 113, a second interlayer insulating layer 114, a second gate insulating layer 115, and a third interlayer insulating layer 116. The organic insulating layers OIL may include a first organic insulating layer 121 and a second organic insulating layer 123.

The substrate 100 may include a glass material, a ceramic material, a metal material, or a plastic. The substrate 100 may include flexible or bendable material. When the substrate 100 is flexible or bendable, the substrate 100 may include a polymer resin, such as polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate, and cellulose acetate propionate (CAP).

The substrate 100 may include a single-layered structure or multi-layered structure of the above material, and may further include an inorganic layer in a case of a multi-layered structure. For example, the substrate 100 may include a first organic base layer 101, a first inorganic barrier layer 102, a second organic base layer 103, and a second inorganic barrier layer 104. Each of the first organic base layer 101 and the second organic base layer 103 may include a polymer resin. The first inorganic barrier layer 102 and the second inorganic barrier layer 104 are barrier layers preventing or reducing penetration of external foreign materials or contaminants, which may each include a single layer or a multilayer, each including an inorganic insulating material such as silicon nitride and/or silicon oxide.

A bottom metal layer BML may be located on the substrate 100. The bottom metal layer BML may include one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the bottom metal layer BML may have a single layer of Mo, a double-layered structure in which a Mo layer and a Pt layer are stacked, or a triple-layered structure in which a Ti layer, an Al layer, and a Ti layer are stacked.

The buffer layer 111 may be located on the bottom metal layer BML. The buffer layer 111 may be an inorganic insulating layer including an inorganic insulating material such as silicon nitride and/or silicon oxide, and may have a single-layered structure or a multi-layered structure, each including the above material.

Silicon semiconductor layers of silicon-based transistors may be located on the buffer layer 111. In this regard, FIG. 4 illustrates a semiconductor layer A1 of the first transistor T1, which corresponds to a portion of a silicon semiconductor pattern SACT. The semiconductor layer A1 may include a channel area C1 and impurity areas located on both sides of the channel area C1 and doped with impurities. FIG. 4 illustrates a second area D1, which is one of the impurity areas located on one side of the channel area C1.

The first gate insulating layer 112 may be located on the silicon semiconductor pattern SACT. The first gate insulating layer 112 may be an inorganic insulating layer including an inorganic insulating material such as silicon oxide, silicon nitride, and/or silicon oxynitride, and may have a single-layered structure or a multi-layered structure, each including the above material.

A gate electrode G1 and a first capacitor electrode CE1 may be located on the first gate insulating layer 112. FIG. 4 illustrates that the gate electrode G1 is integrally formed with the first capacitor electrode CE1. In other words, the gate electrode G1 may perform a function of the first capacitor electrode CE1, or the first capacitor electrode CE1 may perform a function of the gate electrode G1.

The gate electrode G1 and/or the first capacitor electrode CE1 may include Al, Pt, Pd, Ag, Mg, Au, Ni, Nd, Ir, Cr, Li, Ca, Mo, Ti, W, and/or Cu, and may be formed in a single layer or a multi-layer, each including the above material.

The first interlayer insulating layer 113 may be located on the gate electrode G1 and/or the first capacitor electrode CE1. The first interlayer insulating layer 113 may be an inorganic insulating layer including an inorganic insulating material such as silicon oxide, silicon nitride, and/or silicon oxynitride, and may have a single-layered structure or a multi-layered structure, each including the above material.

A second capacitor electrode CE2 may be located on the first interlayer insulating layer 113. The second capacitor electrode CE2 may include Al, Pt, Pd, Ag, Mg, Au, Ni, Nd, Ir, Cr, Li, Ca, Mo, Ti, W, and/or Cu, and may be formed in a single layer or a multi-layer, each including the above material. The second capacitor electrode CE2 may overlap the gate electrode G1 and/or the first capacitor electrode CE1. The second capacitor electrode CE2 may include an opening SOP so that a first connection electrode 171 is connected to the gate electrode G1. The opening SOP may overlap a portion of the gate electrode G1. According to some embodiments, another end of the first connection electrode 171 may be electrically connected to a source area of the third transistor T3.

The second interlayer insulating layer 114 may be located on the second capacitor electrode CE2. The second interlayer insulating layer 114 may be an inorganic insulating layer including an inorganic insulating material such as silicon oxide, silicon nitride, and/or silicon oxynitride, and may have a single-layered structure or a multi-layered structure, each including the above material.

Oxide semiconductor layers may be located on the second interlayer insulating layer 114. In this regard, FIG. 4 illustrates a semiconductor layer A3 of the third transistor T3, which corresponds to a portion of an oxide semiconductor pattern OACT. The semiconductor layer A3 may include a channel area C3 and conductive areas located on both sides of the channel area C3. FIG. 4 illustrates a second area D3, which is one of the conductive areas located on one side of the channel area C3. A vertical distance from the substrate 100 to the semiconductor layer A3 may be greater than a vertical distance from the substrate 100 to the semiconductor layer A1.

A gate electrode G3 may be located below and/or above the semiconductor layer A3. FIG. 4 illustrates that the gate electrode G3 includes a lower gate electrode G3a located below the semiconductor layer A3 and an upper gate electrode G3b located above the semiconductor layer A3. According to some embodiments, any one of the lower gate electrode G3a and the upper gate electrode G3b may be omitted.

The lower gate electrode G3a may include the same material as the second capacitor electrode CE2 and may be positioned on the same layer (e.g., the first interlayer insulating layer 113). The upper gate electrode G3b may be located above the semiconductor layer A3 with the second gate insulating layer 115 therebetween. The upper gate electrode G3b may include Al, Pt, Pd, Ag, Mg, Au, Ni, Nd, Ir, Cr, Li, Ca, Mo, Ti, W, and/or Cu, and may be formed in a single layer or a multi-layer, each including the above material.

FIG. 4 illustrates that the second gate insulating layer 115 is only located between the upper gate electrode G3b and the semiconductor layer A3, but the disclosure is not limited thereto. According to some embodiments, the second gate insulating layer 115 may be formed to entirely cover the substrate 100, like another insulating layer, for example, the first gate insulating layer 112. The second gate insulating layer 115 may be an inorganic insulating layer including an inorganic insulating material such as silicon oxide, silicon nitride, and/or silicon oxynitride, and may have a single-layered structure or a multi-layered structure, each including the above material.

The third interlayer insulating layer 116 may be located on the upper gate electrode G3b. The third interlayer insulating layer 116 may be an inorganic insulating layer including an inorganic insulating material such as silicon oxide, silicon nitride, and/or silicon oxynitride, and may have a single-layered structure or a multi-layered structure, each including the above material.

The first connection electrode 171 and a second connection electrode 172 may be located on the third interlayer insulating layer 116. Each of the first connection electrode 171 and the second connection electrode 172 may include Al, Pt, Pd, Ag, Mg, Au, Ni, Nd, Ir, Cr, Li, Ca, Mo, Ti, W, and/or Cu, and may be formed in a single layer or a multi-layer, each including the above material. For example, the first connection electrode 171 and the second connection electrode 172 may each include a triple-layered structure in which a Ti layer, an Al layer, and a Ti layer are stacked.

The second connection electrode 172 may electrically connect the semiconductor layer A1 to the semiconductor layer A3. The second connection electrode 172 may be connected to a portion of the semiconductor layer A1 (e.g., the second area D1 of FIG. 4) through a contact hole penetrating the inorganic insulating layers between the semiconductor layer A1 and the second connection electrode 172, for example, the first gate insulating layer 112, the first interlayer insulating layer 113, the second interlayer insulating layer 114, and the third interlayer insulating layer 116. The second connection electrode 172 may be connected to a portion of the semiconductor layer A3 (e.g., the second area D3 of FIG. 4) through a contact hole penetrating the third interlayer insulating layer 116 between the semiconductor layer A3 and the second connection electrode 172.

The bottom metal layer BML may have a voltage level of a constant voltage. The bottom metal layer BML may prevent or reduce a problem of afterimages caused by (-) charges by preventing or reducing the (-) charges gathering at a lower portion of the semiconductor layer A1 of the first transistor T1.

The first organic insulating layer 121 may be formed on the second connection electrode 172 and the first connection electrode 171. The first organic insulating layer 121 may include an organic material, such as acrylic, benzocyclobutene (BCB), PI, hexamethyldisiloxane (HMDSO), and/or the like.

The first power voltage line PL may be located on the first organic insulating layer 121. The second organic insulating layer 123 may be located on the first power voltage line PL. The first power voltage line PL may include Al, Pt, Pd, Ag, Mg, Au, Ni, Nd, Ir, Cr, Li, Ca, Ti, and/or W. In some embodiments, the first power voltage line PL may include a triple-layered structure of a Ti layer, an Al layer, and a Ti layer.

The second organic insulating layer 123 may include an organic material, such as BCB, PI, HMDSO, and/or the like.

The light-emitting diode layer DEL may be located on the pixel circuit layer PCL. The light-emitting diode layer DEL may include a display element such as a light-emitting diode. For example, the light-emitting diode layer DEL may include an organic light-emitting diode OLED. The organic light-emitting diode OLED may include a pixel electrode 210, an emission layer 220, and an opposite electrode 230.

The pixel electrode 210 of the organic light-emitting diode OLED may be formed on the second organic insulating layer 123. The emission layer 220 may include a low-molecular-weight organic material or a polymer organic material. At least one layer selected from among a hole injection layer (HIL), a hole transport layer (HTL), an electron transport layer (ETL), and an electron injection layer (EIL) may be further located between the pixel electrode 210 and the opposite electrode 230.

An edge of the pixel electrode 210 may be covered with a bank layer 140, and an inner portion of the pixel electrode 210 may overlap the emission layer 220 through an opening 140OP of the bank layer 140. The pixel electrode 210 may be formed for each organic light-emitting diode OLED, and conversely, the opposite electrode 230 may be formed to correspond to a plurality of organic light-emitting diodes OLED. In other words, the plurality of organic light-emitting diodes OLED may share the opposite electrode 230, and a stacked structure of the pixel electrode 210, the emission layer 220, and a portion of the opposite electrode 230 may correspond to the organic light-emitting diode OLED.

An encapsulation layer 300 may be located on the organic light-emitting diode OLED. The encapsulation layer 300 may include at least one inorganic encapsulation layer and at least one organic encapsulation layer. According to some embodiments, FIG. 4 illustrates that the encapsulation layer 300 includes a first inorganic encapsulation layer 310, an organic encapsulation layer 320, and a second inorganic encapsulation layer 330. Each of the first inorganic encapsulation layer 310 and the second inorganic encapsulation layer 330 may include silicon oxide, silicon nitride, and/or silicon oxynitride, and the organic encapsulation layer 320 may include an organic insulating material.

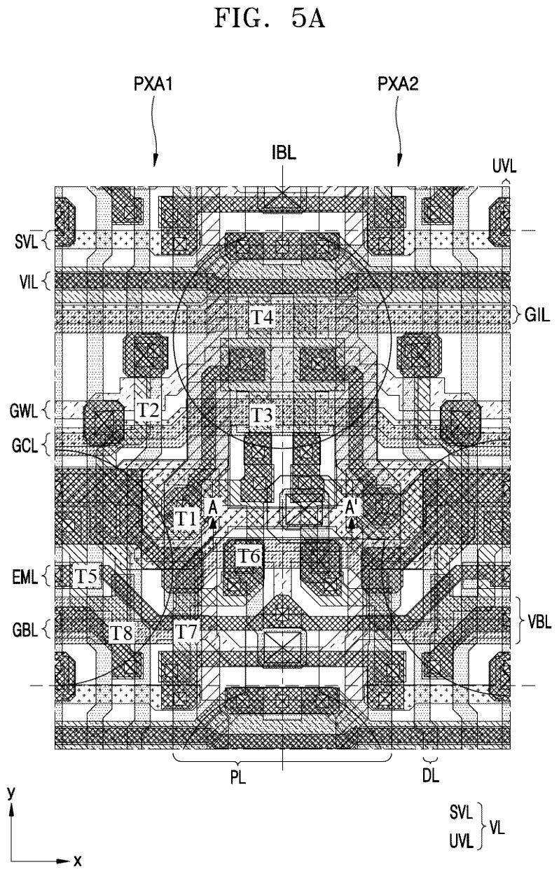

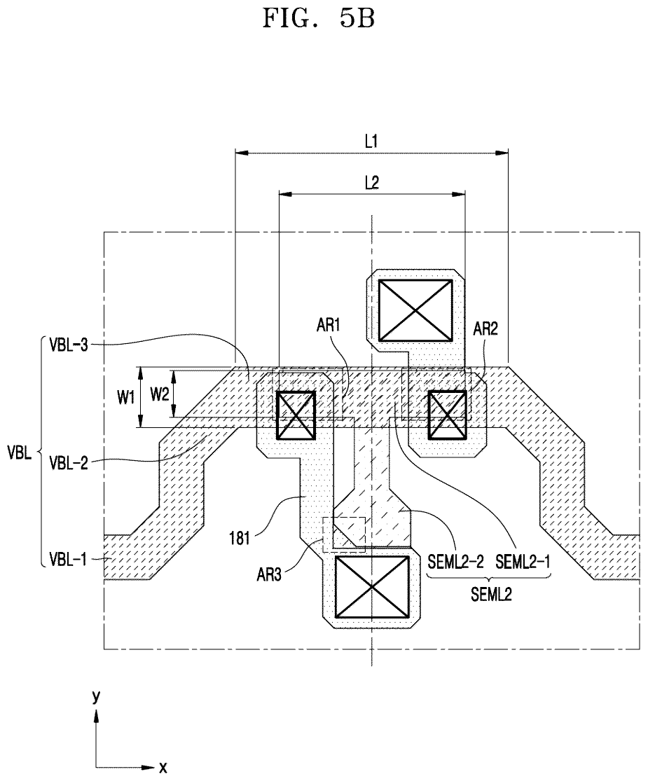

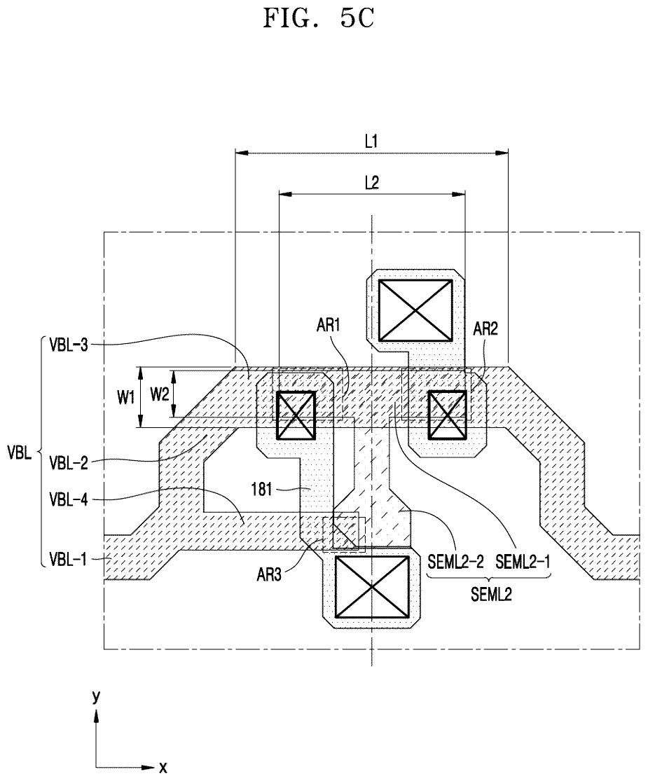

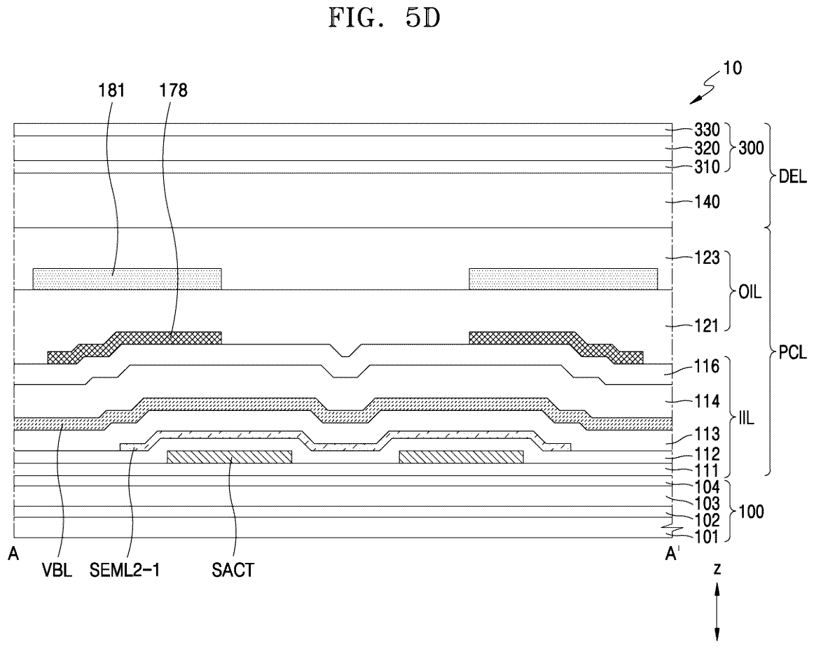

FIG. 5A is a schematic plan view showing the positions of elements located in a pixel circuit of a display panel according to some embodiments. FIG. 5A corresponds to embodiments of the pixel circuit of FIG. 3.

FIG. 5A illustrates pixel areas located on the same row and being adjacent to each other. For example, FIG. 5A illustrates a pixel circuit of a first pixel area PXA1 and a pixel circuit of a second pixel area PXA2. The pixel circuit of the first pixel area PXA1 and the pixel circuit of the second pixel area PXA2 may have a left-right symmetrical structure around a boundary line IBL between the first pixel area PXA1 and the second pixel area PXA2.

Pixel areas located on the same row may share the first gate line GWL, the second gate line GIL, the third gate line GCL, the fourth gate line GBL, the fifth gate line EML, the bias voltage line VBL, the initialization voltage line VL, and the node initialization voltage line VIL.

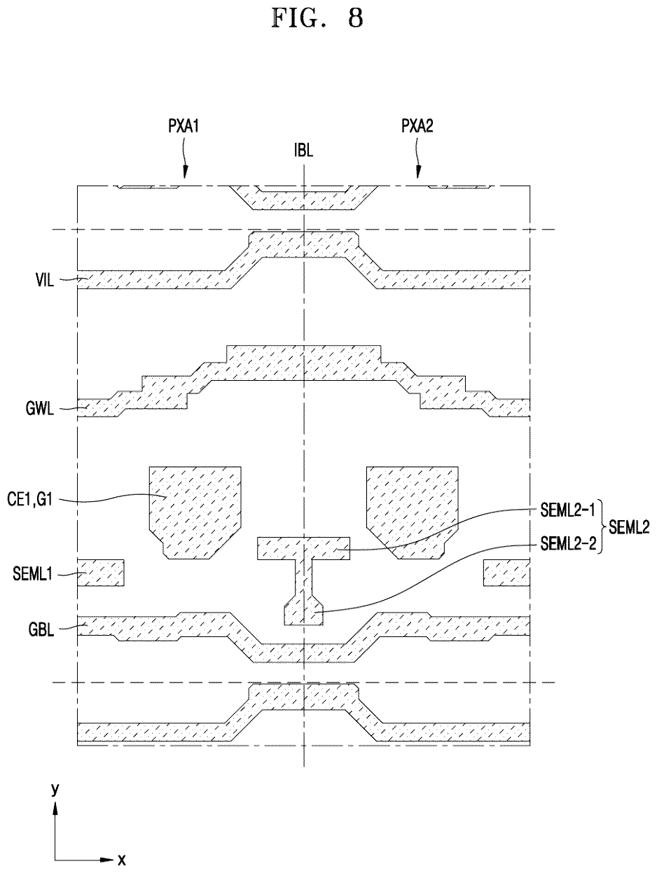

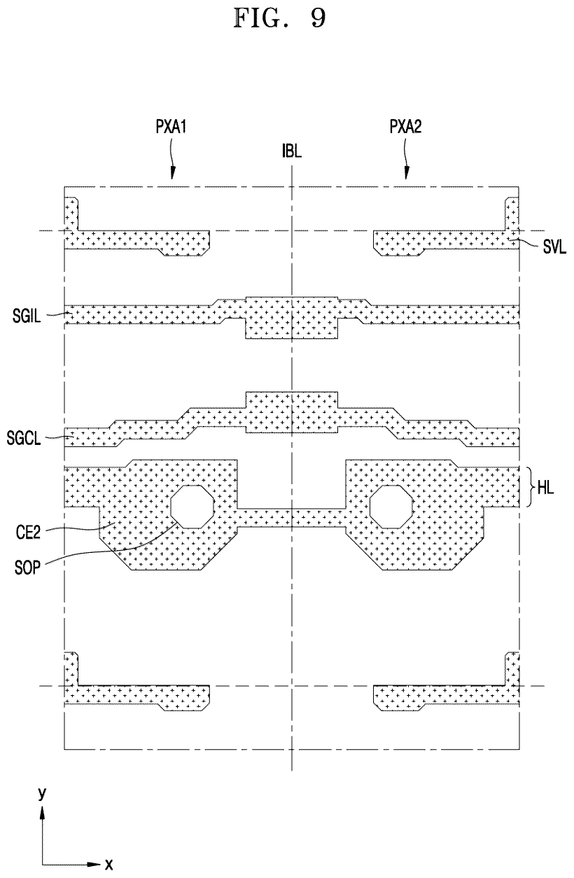

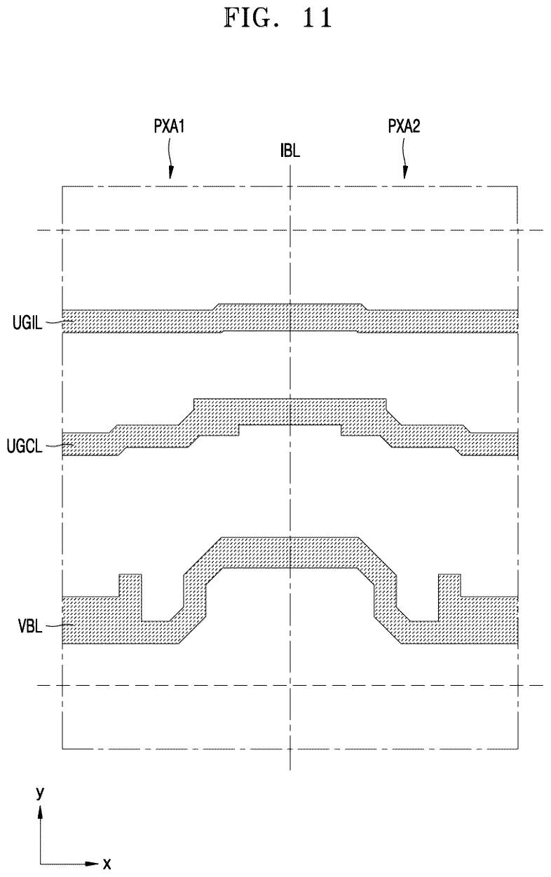

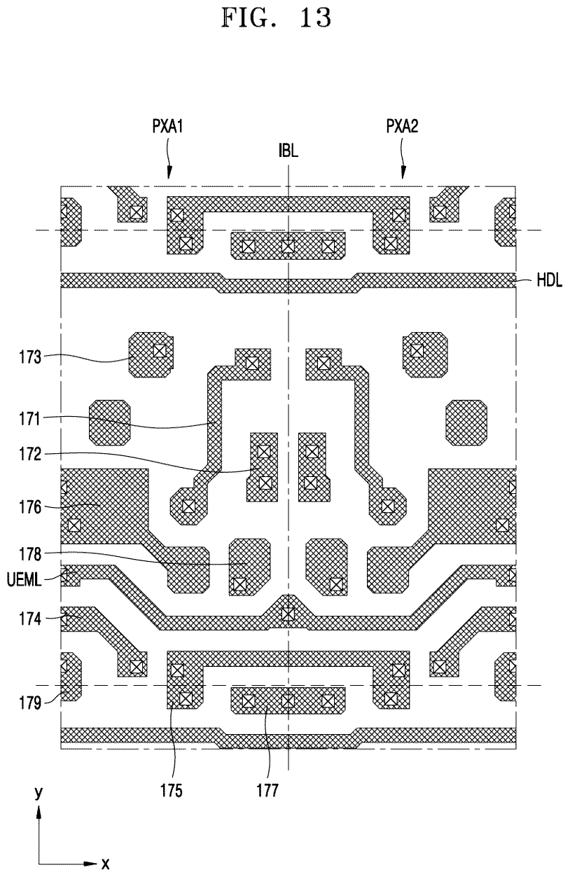

According to some embodiments, as to be described below, the second gate line GIL may include a lower second gate line SGIL (refer to FIG. 9) and an upper second gate line UGIL (refer to FIG. 11). The third gate line GCL may include a lower third gate line SGCL (refer to FIG. 9) and an upper third gate line UGCL (refer to FIG. 11). The fifth gate line EML may include a first lower fifth gate line SEML1 (refer to FIG. 8), a second lower fifth gate line SEML2 (refer to FIG. 8), and an upper fifth gate line UEML (refer to FIG. 13).

FIG. 5B is a schematic plan view showing a portion of FIG. 5A. FIG. 5C is a schematic plan view of a portion of a pixel circuit of a display panel according to some embodiments. FIG. 5D is a cross-sectional view taken along a line A-A′ of FIG. 5A. In FIG. 5D, the same reference numerals as in FIG. 4 represent the same elements.

Referring to FIGS. 5B to 5D, a connection electrode 181 to be described below may overlap at least a portion of the second lower fifth gate line SEML2, which is a conductive layer. For example, the connection electrode 181 may overlap the second lower fifth gate line SEML2 in a first area AR1, a second area AR2, and a third area AR3.

A line to which a constant voltage is applied may be arranged, as a shielding unit, between the connection electrode 181 and the second lower fifth gate line SEML2 in a thickness direction (e.g., a z direction of FIG. 5D), in at least one of the first area AR1, the second area AR2, or the third area AR3 where the connection electrode 181 overlaps the second lower fifth gate line SEML2. For example, the initialization voltage line VL, the node initialization voltage line VIL, or the bias voltage line VBL may be arranged as a shielding unit located between the connection electrode 181 and the second lower fifth gate line SEML2. At this time, when the initialization voltage line VL or the node initialization voltage line VIL is used as a shielding unit located between the connection electrode 181 and the second lower fifth gate line SEML2, the initialization voltage line VL or the node initialization voltage line VIL may be located at a position of the bias voltage line VBL to be described below, and the bias voltage line VBL may be located at a position of the initialization voltage line VL or the node initialization voltage line VIL to be described below. In addition, when the positions of the initialization voltage line VL, the node initialization voltage line VIL, and the bias voltage line VBL are changed as described above, the initialization voltage line VL, the node initialization voltage line VIL, and the bias voltage line VBL may be respectively connected to other elements as described above or to be described below. Hereinafter, for convenience of explanation, a case in which a line located between the connection electrode 181 and the second lower fifth gate line SEML2 is the bias voltage line VBL is mainly described in detail.

The bias voltage line VBL may be located between the connection electrode 181 and the second lower fifth gate line SEML2. In this case, the second lower fifth gate line SEML2 may be located below the bias voltage line VBL, and the connection electrode 181 may be located on the bias voltage line VBL. In addition, the bias voltage line VBL located between the connection electrode 181 and the second lower fifth gate line SEML2 may partially overlap a semiconductor layer. For example, the bias voltage line VBL located between the connection electrode 181 and the second lower fifth gate line SEML2 may overlap the silicon semiconductor pattern SACT. Insulating layers may be located between the bias voltage line VBL and the connection electrode 181 and between the bias voltage line VBL and the second lower fifth gate line SEML2. For example, the insulating layer located between the bias voltage line VBL and the second lower fifth gate line SEML2 may be the first interlayer insulating layer 113. The insulating layer located between the bias voltage line VBL and the connection electrode 181 may include at least one of the second interlayer insulating layer 114, the second gate insulating layer 115, the third interlayer insulating layer 116, and the first organic insulating layer 121.

Referring to FIG. 5B, the bias voltage line VBL may include a first bias voltage line VBL-1 extending in an x direction, a second bias voltage line VBL-2 bent from the first bias voltage line VBL-1, and a third bias voltage line VBL-3 bent from the second bias voltage line VBL-2 and extending in the x direction. The second lower fifth gate line SEML2 may include a first portion SEML2-1 extending in the x direction and a second portion SEML2-2 extending in a y direction from the first portion SEML2-1.

In a plan view, the bias voltage line VBL may completely shield the area where the connection electrode 181 overlaps the second lower fifth gate line SEML2. For example, in a plan view, a portion where the connection electrode 181 overlaps the second lower fifth gate line SEML2 may be located within the bias voltage line VBL. In this case, in a plan view, a portion of the second lower fifth gate line SEML2 may be located within the bias voltage line VBL. For example, the third bias voltage line VBL-3 may have a straight-line form, and a first length L1 of the third bias voltage line VBL-3 may be greater than a second length L2 of the first portion SEML2-1. In addition, a first width W1 of the third bias voltage line VBL-3 may be greater than a second width W2 of the first portion SEML2-1.

Referring to FIG. 5C, the bias voltage line VBL may include the first bias voltage line VBL-1, the second bias voltage line VBL-2, the third bias voltage line VBL-3, and a fourth bias voltage line VBL-4. At this time, the first bias voltage line VBL-1, the second bias voltage line VBL-2, and the third bias voltage line VBL-3 may be the same as those described with reference to FIG. 5B. The fourth bias voltage line VBL-4 may protrude to the third area AR3 from at least one of the first bias voltage line VBL-1, the second bias voltage line VBL-2, or the third bias voltage line VBL-3. At this time, the fourth bias voltage line VBL-4 may shield the third area AR3.

When the bias voltage line VBL is not arranged as described above, a parasitic capacitance may occur between the connection electrode 181 and the second lower fifth gate line SEML2 due to a voltage difference between the connection electrode 181 and the second lower fifth gate line SEML2. In this case, light emitted from a pixel including a pixel circuit may not be uniform due to noise occurring in a signal applied to the connection electrode 181 or the second lower fifth gate line SEML2. However, the above problem may be reduced by arranging a line, to which a constant voltage is applied, between the connection electrode 181 and the second lower fifth gate line SEML2 in at least one of the first area AR1, the second area AR2, and the third area AR3, as described above.

In the above case, the shape of the bias voltage line VBL is not limited to the shapes shown in FIGS. 5B and 5C. For example, the bias voltage line VBL may include any shape and structure that shields at least one of the first area AR1, the second area AR2, or the third area AR3, such as a curved shape, a W shape, a serpentine shape, a zigzag shape, a shape having at least a portion bent, or the like, in addition to a straight-line shape.

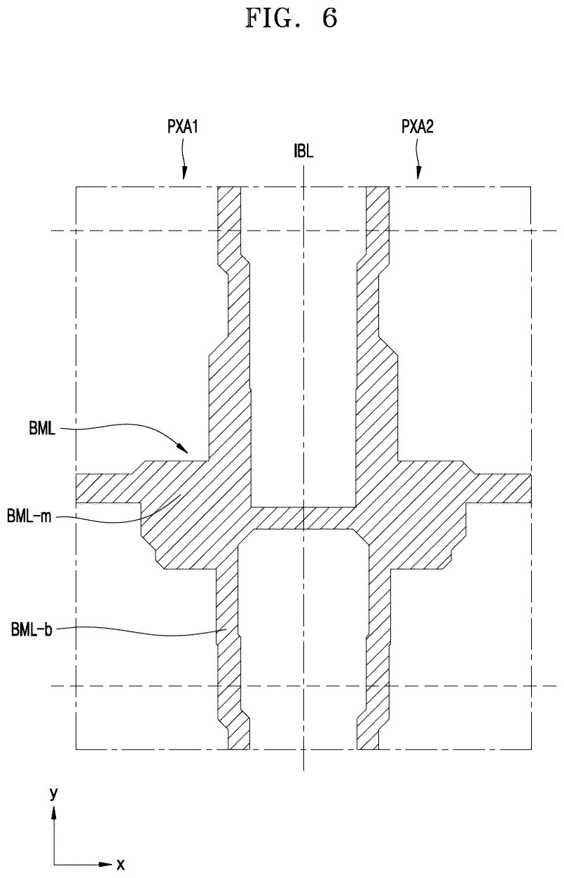

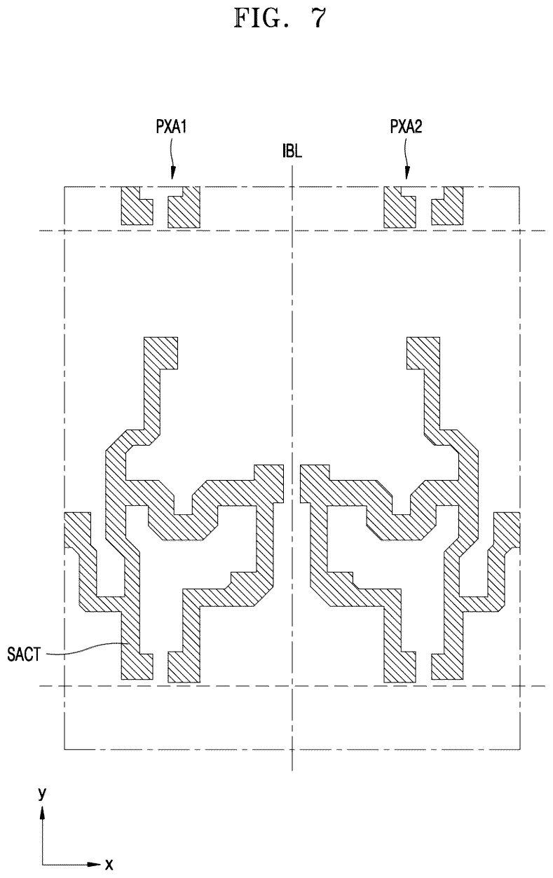

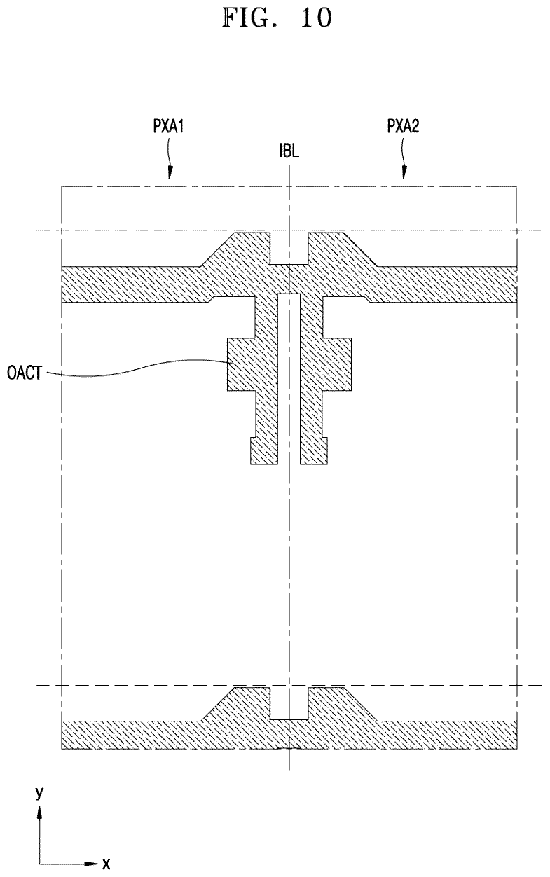

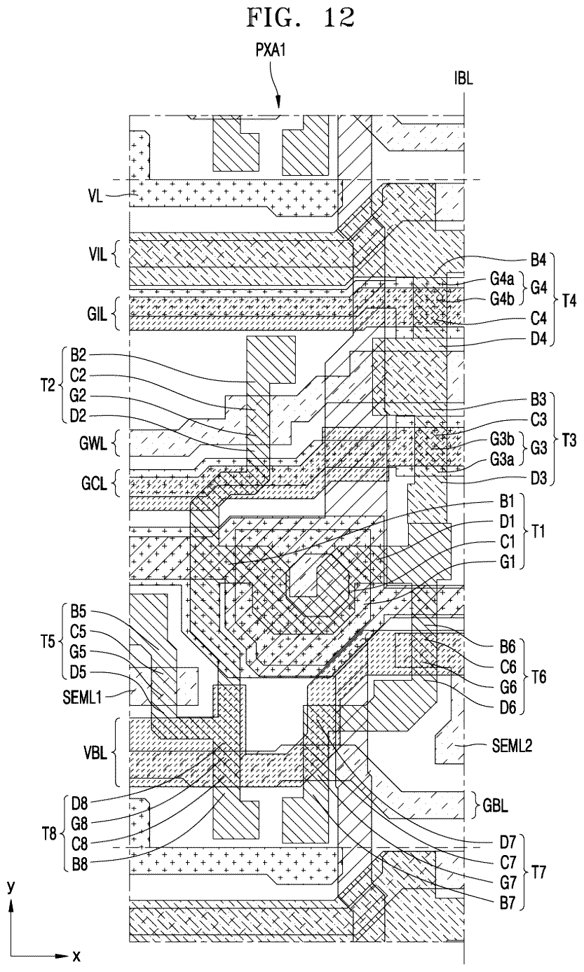

FIGS. 6 to 15 are schematic layout diagrams showing, by each layer, elements located in a pixel circuit of a display panel according to some embodiments. FIG. 12 is a plan view in which the elements of FIGS. 6 to 11 overlap each other.

Because the same elements are located on each layer of the first pixel area PXA1 and the second pixel area PXA2, elements of a pixel circuit located in the first pixel area PXA1 are mainly described for convenience of explanation.

Referring to FIGS. 4, 5A, and 6, the bottom metal layer BML may be located on the substrate 100. The bottom metal layer BML may include a portion (hereinafter referred to as a main portion BML-m) located in each of the first pixel area PXA1 and the second pixel area PXA2. Each main portion BML-m may be connected to other portions (hereinafter referred to as branch portions BML-b) extending in an x direction and/or a y direction.

Referring to FIGS. 4, 5A, and 7, the buffer layer 111 may be located on the bottom metal layer BML, and the silicon semiconductor pattern SACT may be located on the buffer layer 111. The silicon semiconductor pattern SACT may include a silicon-based material, for example, polycrystalline silicon.

The silicon semiconductor pattern SACT may have curved shapes in various shapes. The silicon semiconductor pattern SACT may include a channel area, a first area and a second area, which are located on both sides of the channel area, of each of the first transistor T1, the second transistor T2, the fifth transistor T5, the sixth transistor T6, the seventh transistor T7, and the eighth transistor T8. One of the first area and the second area may be a source area, and the other one may be a drain area.

Referring to FIG. 12, the silicon semiconductor pattern SACT may include the channel area C1, a first area B1, and the second area D1 of the first transistor T1, a channel area C2, a first area B2, and a second area D2 of the second transistor T2, a channel area C5, a first area B5, and a second area D5 of the fifth transistor T5, a channel area C6, a first area B6, and a second area D6 of the sixth transistor T6, and a channel area C7, a first area B7, and a second area D7 of the seventh transistor T7. The silicon semiconductor pattern SACT may further include a channel area C8, a first area B8, and a second area D8 of the eighth transistor T8. Because the channel area C1 of the first transistor T1 may be formed long by having a curve, a driving range of a gate voltage applied to a gate electrode may be widened. The shape of the channel area C1 may have various embodiments such as ‘⊏,’‘ [symbol] ,’ ‘S,’ ‘M,’ W,’ or the like.

At least one portion of the silicon semiconductor pattern SACT may overlap the bottom metal layer BML. For example, the channel area C1 of the first transistor T1 included in the silicon semiconductor pattern SACT may overlap the main portion BML-m, which is a portion of the bottom metal layer BML.

Referring to FIGS. 4, 5A, and 8, the first gate insulating layer 112 may be located on the buffer layer 111 to cover the silicon semiconductor pattern SACT, the gate electrode G1 of the first transistor T1 may be arranged in an island shape on the first gate insulating layer 112, and the first gate line GWL, the first lower fifth gate line SEML1, the second lower fifth gate line SEML2, the node initialization voltage line VIL, and the fourth gate line GBL may be arranged on the first gate insulating layer 112 to extend in the x direction.

The gate electrode G1 of the first transistor T1 may be the first capacitor electrode CE1, which is the first electrode of the first capacitor Cst. A gate electrode G2 of the second transistor T2 may be portions of the first gate line GWL, which intersect (overlap) the silicon semiconductor pattern SACT. A gate electrode G5 of the fifth transistor T5 and a gate electrode G6 of the sixth transistor T6 may respectively be portions of the first lower fifth gate line SEML1 and the second lower fifth gate line SEML2, which intersect the silicon semiconductor pattern SACT. A gate electrode G7 of the seventh transistor T7 may be a portion of the fourth gate line GBL, which intersects the silicon semiconductor pattern SACT. A gate electrode G8 of the eighth transistor T8 may be a portion of the fourth gate line GBL, which intersects the silicon semiconductor pattern SACT.

Referring to FIGS. 4, 5A, and 9, the first interlayer insulating layer 113 may be located on the first gate insulating layer 112, and a lower initialization voltage line SVL, an electrode voltage line HL, the lower third gate line SGCL, and the lower second gate line SGIL may be located on the first interlayer insulating layer 113 to extend in the x direction.

A portion of the electrode voltage line HL is the second capacitor electrode CE2, which is the second electrode of the first capacitor Cst, which may cover the first capacitor electrode CE1 of the first capacitor Cst. The second capacitor electrodes CE2 of the first capacitors Cst respectively located in the first pixel area PXA1 and the second pixel area PXA2 may be connected to each other by the electrode voltage line HL. The opening SOP may be formed in the second capacitor electrode CE2 of the first capacitor Cst.

Referring to FIGS. 4, 5A, and 10, the second interlayer insulating layer 114 may be located on the first interlayer insulating layer 113, and the oxide semiconductor pattern OACT may be located on the second interlayer insulating layer 114. The oxide semiconductor pattern OACT of the first pixel area PXA1 may be connected to and integrally provided with the oxide semiconductor pattern OACT of the second pixel area PXA2. The oxide semiconductor pattern OACT may include a channel area, a first area and a second area on both sides of the channel area of each of the third transistor T3 and the fourth transistor T4. One of the first area and the second area may be a source area, and the other one may be a drain area. A source area and a drain area of a semiconductor pattern may respectively correspond to the first terminal (or a second terminal) and the second terminal (or a first terminal) of a transistor described in FIG. 3. The source area or the drain area may be interpreted as a source electrode or a drain electrode of a transistor according to some cases.

Referring to FIG. 12, the oxide semiconductor pattern OACT may include the channel area C3, a first area B3, and the second area D3 of the third transistor T3 and a channel area C4, a first area B4, and a second area D4 of the fourth transistor T4.

Referring to FIGS. 4, 5A, and 11, the second gate insulating layer 115 may be located on the second interlayer insulating layer 114, and the upper second gate line UGIL, the upper third gate line UGCL, and the bias voltage line VBL may be located on the second gate insulating layer 115 to extend in the x direction.

The upper second gate line UGIL may overlap the lower second gate line SGIL. The upper second gate line UGIL may be electrically connected to the lower second gate line SGIL through a contact hole. The upper third gate line UGCL may be electrically connected to the lower third gate line SGCL through a contact hole.

A gate electrode G3 of the third transistor T3 may be a portion of each of the upper third gate line UGCL and the lower third gate line SGCL, which intersects (overlaps) the oxide semiconductor pattern OACT. The gate electrode G3 of the third transistor T3 may include the lower gate electrode G3a, which is a portion of the lower third gate line SGCL, and the upper gate electrode G3b, which is a portion of the upper third gate line UGCL. A gate electrode G4 of the fourth transistor T4 may be a portion of each of the upper second gate line UGIL and the lower second gate line SGIL, which intersects (overlaps) the oxide semiconductor pattern OACT. The gate electrode G4 of the fourth transistor T4 may include a lower gate electrode G4a, which is a portion of the lower second gate line SGIL, and an upper gate electrode G4b, which is a portion of the upper second gate line UGIL. That is, the third transistor T3 and the fourth transistor T4 may each have a dual-gate structure having gate electrodes respectively on the upper and lower portions of the oxide semiconductor pattern OACT.

Referring to FIGS. 4, 5A, and 13, the third interlayer insulating layer 116 may be located on the second gate insulating layer 115, and a horizontal data line HDL and the upper fifth gate line UEML may be located on the third interlayer insulating layer 116 to extend in the x direction. In addition, first to ninth connection electrodes 171, 172, 173, 174, 175, 176, 177, 178, and 179 may be located on the third interlayer insulating layer 116.

One end of the first connection electrode 171 may be electrically connected to the oxide semiconductor pattern OACT by being in contact with the oxide semiconductor pattern OACT through a contact hole. The one end of the first connection electrode 171 may be electrically connected to the first area B3 of the third transistor T3 and the second area D4 of the fourth transistor T4. Another end of the first connection electrode 171 may be connected to the gate electrode G1 of the first transistor T1 through a contact hole. At this time, the contact hole may be located within the opening SOP of the second capacitor electrode CE2 of the first capacitor Cst to be spaced apart from an edge of the opening SOP.

The second connection electrode 172 may be electrically connected to the second area D1 of the first transistor T1 and the first area B6 of the sixth transistor T6 through a contact hole. The second connection electrode 172 may be electrically connected to the second area D3 of the third transistor T3 through a contact hole.

The third connection electrode 173 may be electrically connected to the first area B2 of the second transistor T2 through a contact hole.

The fourth connection electrode 174 may be electrically connected to the first area B8 of the eighth transistor T8 through a contact hole. The fourth connection electrode 174 may be electrically connected to the bias voltage line VBL through a contact hole.

The fifth connection electrode 175 may be electrically connected to the lower initialization voltage line SVL. The fifth connection electrode 175 may be electrically connected to the first area B7 of the seventh transistor T7 through a contact hole.

The sixth connection electrode 176 may be electrically connected to the first area B5 of the fifth transistor T5 through a contact hole. The sixth connection electrode 176 may be electrically connected to the electrode voltage line HL through a contact hole.

The seventh connection electrode 177 may be electrically connected to the first area B4 of the fourth transistor T4. The seventh connection electrode 177 may be electrically connected to the node initialization voltage line VIL through a contact hole. The node initialization voltage line VIL may be electrically connected to the first area B4 of the fourth transistor T4 through the seventh connection electrode 177.

For example, the eighth connection electrode 178 may be electrically connected to the second area D6 of the sixth transistor T6 through contact holes penetrating the first gate insulating layer 112, the first interlayer insulating layer 113, the second interlayer insulating layer 114, and the third interlayer insulating layer 116.

The ninth connection electrode 179 may be electrically connected to the lower initialization voltage line SVL through a contact hole.

The upper fifth gate line UEML may overlap the first lower fifth gate line SEML1 and the second lower fifth gate line SEML2. The upper fifth gate line UEML may be electrically connected (e.g., directly electrically connected) to the first lower fifth gate line SEML1 and the second lower fifth gate line SEML2 through contact holes. At this time, a portion of the upper fifth gate line UEML may be arranged to cross a portion of the bias voltage line VBL in a plan view. For example, the second bias voltage line VBL-2 shown in FIGS. 5B and 5C may cross the upper fifth gate line UEML.

Referring to FIGS. 4, 5A, and 14, the first organic insulating layer 121 may be located on the third interlayer insulating layer 116, the connection electrode 181 may be located on the first organic insulating layer 121, and an upper initialization voltage line UVL, the data line DL, a vertical data line VDL, and the first power voltage line PL may be arranged on the first organic insulating layer 121 to extend in the y direction. Various conductive layers may be further located on the first organic insulating layer 121.

The upper initialization voltage line UVL may be electrically connected to the ninth connection electrode 179 through a contact hole. Accordingly, the upper initialization voltage line UVL may be electrically connected to the lower initialization voltage line SVL.

The vertical data line VDL may be electrically connected to the horizontal data line HDL through a contact hole. The data line DL may be electrically connected to the third connection electrode 173 through a contact hole to be electrically connected to the first area B2 of the second transistor T2.

The first power voltage line PL may be electrically connected to the sixth connection electrode 176 through a contact hole. The first power voltage line PL extending in the y direction may be connected to the sixth connection electrode 176 extending in the x direction to have a mesh structure.

The connection electrode 181 may be electrically connected to the eighth connection electrode 178 through a contact hole to be electrically connected to the second area D6 of the sixth transistor T6.

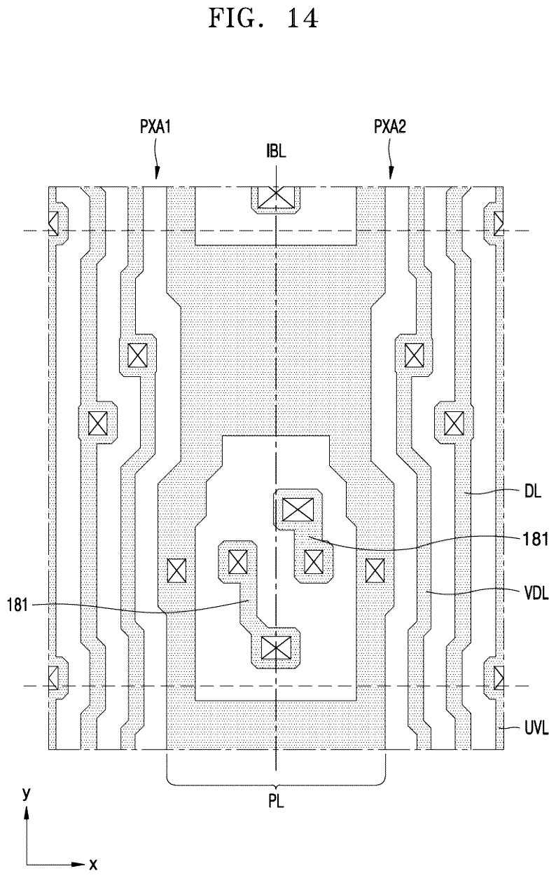

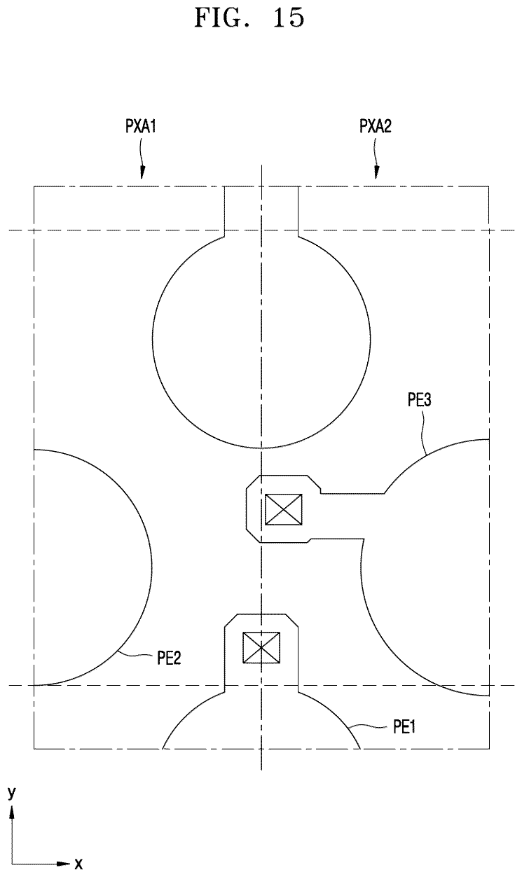

Referring to FIGS. 4, 5A, and 15, the second organic insulating layer 123 may be located on the first organic insulating layer 121, and the pixel electrode 210 may be located on the second organic insulating layer 123. FIG. 15 illustrates a pixel electrode PE1 of a first pixel, a pixel electrode PE2 of a second pixel, and a pixel electrode PE3 of a third pixel. According to some embodiments, the first pixel may be a green pixel, the second pixel may be a red pixel, and the third pixel may be a blue pixel. In addition, the connection electrode 181 may be connected to one pixel electrode 210. For example, the connection electrode 181 located on the left side of FIG. 14 may electrically connect the pixel electrode PE2 of the second pixel to the pixel circuit of the first pixel area PXA1, and the connection electrode 181 located on the right side of FIG. 14 may electrically connect the pixel electrode PE3 of the third pixel to the pixel circuit of the second pixel area PXA2.

The bank layer 140 may be located on the pixel electrode 210. The opening 140OP corresponding to an emission area of each pixel may be defined in the bank layer 140. The emission layer 220 and a portion of the opposite electrode 230 may be located in the opening 140OP of the bank layer 140.

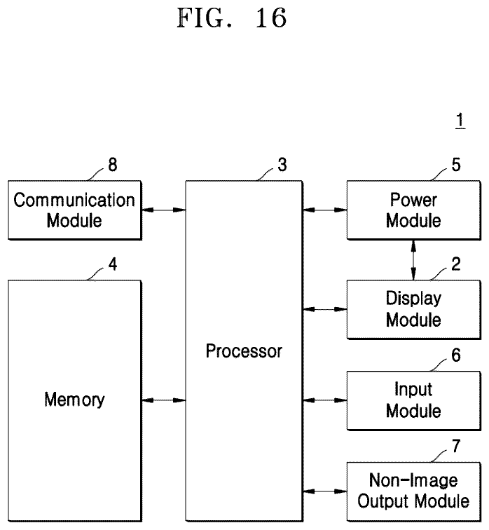

FIG. 16 is a block diagram of an electronic device according to some embodiments.

Referring to FIG. 16, an electronic device 1 according to some embodiments may include a display module 2 including a display panel, a processor 3, a memory 4, and a power module 5.

The processor 3 may include at least one of a central processing unit (CPU), an application processor (AP), a graphics processing unit (GPU), a communication processor (CP), an image signal processor (ISP), or a controller. According to some embodiments, the processor 3 may be divided into two or more to be provided from a functional or structural perspective. For example, the processor 3 may include a main processor in a form of a first drive chip including a central processing unit, and an auxiliary processor in a form of a second drive chip including a controller that receives an image signal from the main processor and processes the image signal to match interface specifications of the display module 2.

The memory 4 may include at least one of non-volatile memory or volatile memory. Data information necessary for an operation of the processor 3 or the display module 2 may be stored in the memory 4. When the processor 3 executes an application stored in the memory 4, an image data signal and/or an input control signal may be transmitted to the display module 2, and the display module 2 may process the received signal and output image information through a display screen.

The power module 5 may include a power supply module, such as a power adapter or a battery device, and a power conversion module that generates power necessary for an operation of the electronic device 1 by converting power supplied by the power supply module. Power conversion by the power conversion module may include direct current (DC)-DC conversion, alternating current (AC)-DC conversion, and DC-AC conversion, but is not limited thereto.

The electronic device 1 may further include an input module 6, a non-image output module 7, and/or a communication module 8.

The input module 6 may provide input information to the processor 3 and/or the display module 2. The input module 6 may include various types of sensor modules as well as a physical button, a keyboard, and a microphone. Examples of the sensor modules may include a touch sensor, a pressure sensor, a distance sensor, a position sensor, a digitizer, a motion recognition sensor, a light receiving sensor, a photoelectric conversion sensor, a temperature sensor, as well as a biometric sensor, such as a blood pressure sensor, a blood sugar sensor, an electrocardiogram sensor, a heart rate sensor, or the like.

The non-image output module 7 may serve to receive information other than an image received from the processor 3 and provide the received information to the user. Examples of the non-image output modules 7 may include an audio module, a haptic module, a light-emitting module, or the like, and may include other functional modules unique to the electronic device 1 (e.g., a cooling module or the like of a refrigerator).

The communication module 8 is a module responsible for transmitting and receiving information between the electronic device 1 and an external device, which may include a transmission unit and a reception unit. The communication module 8 may include various types of wireless communication modules, such as a mobile communication module, a Wi-Fi module, a Bluetooth module, or may include various types of wired communication modules.

At least one of the configurations of the electronic device 1 described above may be included in the display panel according to the embodiments described above. In addition, some of the modules mentioned-above may be included in the display panel, and the others may be provided separately from the display panel. For example, the display panel may include the display module 2, and the processor 3, the memory 4, and the power module 5 may be provided in a form of other devices within the electronic device 1 instead of the display panel. As another example, the power module 5 may be provided within the display panel and may also supply power to the processor 3 and the memory 4, which are provided within the electronic device 1 instead of the display panel, but the disclosure is not limited thereto.

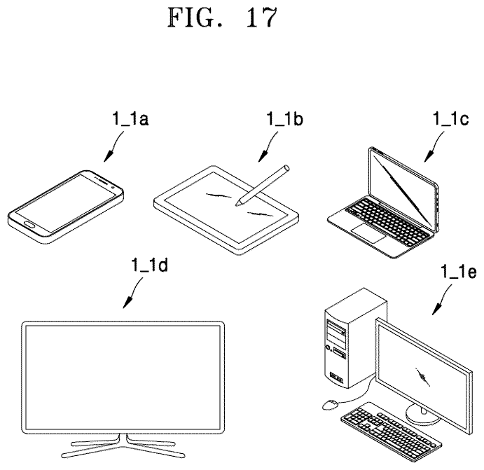

FIGS. 17 to 19 are schematic diagrams of electronic devices according to various embodiments. FIGS. 17 to 19 illustrate examples of various electronic devices to which display panels according to some embodiments are applied.

FIG. 17 shows a smartphone 1_1a, a tablet personal computer 1_1b, a laptop 1_1c, a television (TV) 1_1d, and a desk monitor 1_1e, as examples of an electronic device.

The smartphone 1_1a may include an input module, such as a touch sensor, and a communication module, in addition to the display module. The smartphone 1_1a may process information received through the communication module or other input modules and display the information through a display module of a display panel.

Similarly to the smartphone 1_1a, the tablet PC 1_1b, the laptop 1_1c, the TV 1_1d and the desk monitor 1_1e may each include a display module and an input module, and may further include a communication module in some cases.

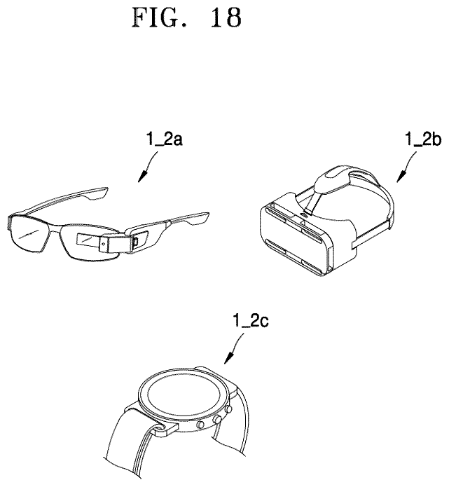

FIG. 18 illustrates an example in which an electronic device including a display module is applied to a wearable electronic device. A wearable electronic device may include smart glasses 1_2a, a head-mounted display 1_2b, and a smartwatch 1_2c.

The smart glasses 1_2a and the head-mounted display 1_2b may include a display module emitting a display image and a reflector reflecting the emitted display image to provide the same to the user's eyes, thereby providing the user with a virtual reality or augmented reality screen.

The smartwatch 1_2c may include a biometric sensor as an input device and provide the user with biometric information recognized by the biometric sensor through the display module.

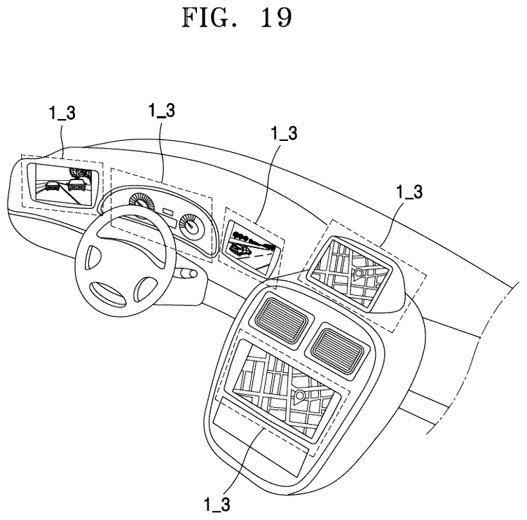

FIG. 19 illustrates an example in which an electronic device including a display module is applied to a vehicle. For example, an electronic device 1_3 may be applied to a dashboard, a center fascia or the like of a vehicle, a center information display (CID) located on the dashboard of the vehicle, a room-mirror display replacing a side mirror or the like.

According to some embodiments, the electronic devices to which the display panel according to some embodiments is applied may include various home appliances that display information through display modules, such as refrigerators, a washing machines, dryers, air-conditioners, and robot vacuum cleaners, as well as devices mainly displaying screens, such as billboard electronic boards, game consoles, or the like. In addition, when the display module has a function of transmitting light, the display module may be applied to electronic devices, such as smart windows or transparent display panels displaying a background and a display image together. Types of electronic devices according to some embodiments are not limited thereto, and application of various other electronic devices which are not described as examples may also be possible.

The display panel and electronic device according to some embodiments may provide a relatively clear image.

The display panel and electronic device according to some embodiments may have reduced signal interference between conductive patterns arranged in different layers.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
at least one display element;
a pixel circuit connected to the at least one display element and comprising a conductive layer configured to receive an emission control signal;
a connection electrode on the conductive layer, at least partially overlapping the conductive layer in a plan view, and connected to a pixel electrode of the at least one display element; and
a shielding unit between the conductive layer and the connection electrode to overlap a portion of the conductive layer where the conductive layer and the connection electrode overlap each other.

2. The display panel of claim 1, wherein the shielding unit is configured to receive an initialization voltage or a bias voltage.

3. The display panel of claim 1, wherein the shielding unit has at least a portion bent.

4. The display panel of claim 1, wherein a width of the shielding unit in a first direction is greater than a width of a portion of the conductive layer, the portion overlapping the shielding unit.

5. The display panel of claim 1, wherein the conductive layer comprises:
a first portion; and
a second portion extending from the first portion in a direction different from a longitudinal direction of the first portion.

6. The display panel of claim 1, wherein the pixel circuit further comprises a semiconductor layer overlapping at least a portion of the conductive layer.

7. The display panel of claim 6, wherein the semiconductor layer comprises polycrystalline silicon.

8. The display panel of claim 1, further comprising an emission control line on a different layer from the conductive layer of the pixel circuit and connected to the conductive layer to apply the emission control signal to the conductive layer.

9. The display panel of claim 8, wherein at least a portion of the shielding unit crosses the emission control line.

10. The display panel of claim 8, wherein the shielding unit and the emission control line extend in a same direction.

11. The display panel of claim 8, wherein the conductive layer is directly connected to the emission control line.

12. The display panel of claim 1, wherein a constant voltage is applied to the shielding unit.

13. The display panel of claim 1, further comprising an insulating layer between the shielding unit and the conductive layer.

14. A display panel comprising:
at least one display element;
a pixel circuit connected to the at least one display element and comprising a conductive layer configured to receive an emission control signal;
a connection electrode on the conductive layer, at least partially overlapping the conductive layer in a plan view, and connected to a pixel electrode of the at least one display element; and
a shielding unit between the conductive layer and the connection electrode to overlap a portion of the conductive layer where the conductive layer and the connection electrode overlap each other, and comprising an initialization voltage line or a bias voltage line configured to receive a constant voltage.

15. An electronic device comprising:
a display panel; and
a memory connected to the display panel,
wherein the display panel comprises:
at least one display element;
a pixel circuit connected to the at least one display element and comprising a conductive layer configured to receive an emission control signal;
a connection electrode on the conductive layer, at least partially overlapping the conductive layer in a plan view, and connected to a pixel electrode of the at least one display element; and
a shielding unit between the conductive layer and the connection electrode to overlap a portion of the conductive layer where the conductive layer and the connection electrode overlap each other.

16. The electronic device of claim 15, wherein the shielding unit configured to receive an initialization voltage or a bias voltage.

17. The electronic device of claim 15, wherein a width of the shielding unit in a first direction is greater than a width of a portion of the conductive layer, the portion overlapping the shielding unit.

18. The electronic device of claim 15, further comprising an emission control line on a different layer from the conductive layer of the pixel circuit and connected to the conductive layer to apply the emission control signal to the conductive layer.

19. The electronic device of claim 18, wherein the conductive layer is directly connected to the emission control line.

20. The electronic device of claim 15, wherein a constant voltage is applied to the shielding unit.
